(19) United States
(12) Patent Application Publication
(10) Pub. No.: US 2011/0162694 A1
(43) Pub. Date: Jul. 7, 2011

(54) Support for Solar Cells and Method for Producing an Assembly of Solar Cells

(75) Inventors: Jens Kalmbach, Pfalzgrafenweiler (DE); Walter Feist, Vs-Villingen (DE); Gerhard Klingebiel, Vs-Villingen (DE); Patrik Müller, Reute (CH)

(73) Assignee: Schmid Technology Systems GmbH, Niedereschach (DE)

(21) Appl. No.: 13/036,855

(22) Filed: Feb. 28, 2011

Related U.S. Application Data
(63) Continuation of application No. PCT/EP2009/006267, filed on Aug. 28, 2009.

(30) Foreign Application Priority Data
Aug. 29, 2008 (DE) 10 2008 046 328.0

(51) Int. Cl. H01L 31/048; H01L 31/18

(52) U.S. Cl. 136/251; 438/66; 257/E31.113

(57) ABSTRACT

A carrier for a plurality of solar cells has a dedicated holding location for each cell for the purpose of mounting it. The carrier is designed like a plate and substantially as a closed plate, each holding location having suction means for a mounted solar cell. A plurality of small holes or passages are provided per holding location in order to come at a mounted solar cell or to reach the latter even from the other side of the carrier at its underside mounted thereon, for example in order to carry out contact soldering.

### CROSS-REFERENCE TO RELATED APPLICATIONS

This application is a continuation of PCT Application No. PCT/EP2009/006267, filed Aug. 28, 2009, and claims priority to DE 10 2008 046 328.0 filed Aug. 29, 2008, the disclosures of which are hereby incorporated by reference in their entirety.

### FIELD OF APPLICATION AND PRIOR ART

The invention relates to a carrier for a plurality of solar cells and to a method for producing an assembly of solar cells with one another by means of such a carrier.

When a plurality of solar cells are being connected or interconnected to form a module, a first step is usually to produce chains or so-called strings from five to ten solar cells. This is described in EP 1 748 495 A1, for example. By way of example, neighbouring solar cells are brought into electrical contact with one another and also fixed to one another mechanically. In the process, the solar cells can be arranged on a working surface or the like. Subsequently, these chains or strings are laid with the front sides onto a glass plate and then a module is produced therefrom.

It is very important in this case that a module with a prescribed number of solar cells is kept as small as possible or not unnecessarily made too large. Furthermore, the solar cells are very sensitive and valuable and so they should be treated as gently as possible mechanically. An arrangement of the solar cells, which uses as little area as possible should be provided such that they can be connected with the least possible spacing from one another, and specifically in all directions. This requires a very good and very accurate positional fixing.

### OBJECT AND SOLUTION

It is the object of the invention to provide an above-described carrier and a method for using this carrier with the aid of which carrier and method it is possible to dispose of problems of the prior art and, in particular, for solar cells to be fastened on the carrier for the purpose of further processing and/or connection to one another in a fashion which is as good and mechanically gentle as possible.

This object is achieved by a carrier having the features of claim 1 and by a method for using said carrier having the features of claim 17. Advantageous and preferred refinements are the subject matter of the further claims and will be explained in more detail below. Some of the features will be described only for the apparatus or only for the method. However, they shall be applicable for the method as well as for the apparatus. The wording of the claims is incorporated in the content of the description by express reference.

A dedicated holding location is provided for each solar cell on the carrier. According to the invention, the carrier is designed like a plate and substantially as a closed plate. Each holding location has suction means for a solar cell mounted thereon, the suction means being distributed in two dimensions or extended in two dimensions on the holding location. A plurality of small holes and/or passages are provided per holding location in order to come at a solar cell mounted thereon, and/or in order to reach said cell, or to come at it for processing, even at that underside with which it is mounted on the carrier. Thus, it is therefore possible to process it through the carrier, for example in a soldering operation for soldering on contact wires. The two-dimensional suction of the solar cells onto the carrier or the holding locations means that holding and fixing are achieved gently and without mechanical loading. Owing to the two dimensional suction, the holding force is also distributed over a relatively large area of the solar cell such that it is possible to avoid instances of point loading which can possibly lead to damage. The advantage of fixing with the aid of suction also resides in the fact that no mechanically moving parts are needed directly or subsequently on the solar cell. Owing to the holding locations respectively provided for each solar cell, each solar cell can be fastened and/or fixed and held after individual mounting. This additionally simplifies and improves a positionally accurate fixing of many solar cells which are mounted on the carrier, for example by means of computer- and video-controlled robot arms. It is possible in this case for the solar cells to be mounted individually and for each mounted solar cell to be fixed immediately by activating the suction means. Thus, it can be ensured that there really is optimum arrangement and assignment of the solar cells relative to one another. The carrier therefore serves for temporarily holding the solar cells on itself during a processing step, the final step being to remove the interconnected solar cells from the carrier for the purpose of further machining or processing.

In a refinement of the invention, the holding locations are advantageously substantially of the same design, in particular of identical design. The outlay on designing and producing a carrier can thus be reduced. For example, it is possible to provide sixty holding locations on one carrier in order to fabricate a module with sixty solar cells.

It can be provided in a further refinement of the invention that all the holding locations are equally distributed at an equal spacing from one another. It is particularly advantageous for the solar cells to be arranged along columns and rows, for example the so-called strings along columns, and a plurality of, for example six, strings next to one another as rows. The spacing of the holding locations can in this case be a few mm up to 2 cm, for example. The spacing of mounted solar cells from one another should then be 2 mm to 3 mm, or even less again.

In a further refinement of the invention, it is provided that the suction means of a holding location stretch over the largest region of the area of this holding location, or occupy the largest region. This is advantageously at least 80% of the area of the holding location. It is particularly advantageous for a holding location to be fastened somewhat smaller than a solar cell mounted thereon such that the suction means occupy at least 70% to 80% of the area of a solar cell. It is possible to provide around the suction means an edge that consists, for example, of a somewhat softer material, which promotes the production of a partial vacuum for the purpose of sucking the solar cell, and also ensures that the solar cell is supported without being scratched.

The suction means are advantageously provided in the middle or in the central region of the holding location. It is particularly advantageous for said means to expose only a narrow edge region of the holding location, for example with a width of approximately 1 cm or even less.

The suction means preferably have a surface made from air-pervious or porous material. This can, for example, be a relatively stable or pressure-proof, but porous or foam-like plastic. The surface of this material advantageously forms the surface of the suction means, that is to say also the area on which the solar cells rest with their mounted underside. The surface of the suction means is advantageously approximately in a plane with the remaining surface of the carrier such that it is possible to apply a partial vacuum and a suction, in particular without causing the solar cell appreciably to be bent or cambered towards the suction means.

In a further refinement of the invention, the air-pervious or porous material of the above described suction means is substantially sealed towards the side, in particular also downwards. A vacuum connection to the material or a suction member formed therefrom can be provided both from below and from the side, possibly for a particularly good production of a partial pressure at a plurality of points per holding location.

In an advantageous refinement of the invention, each holding location or its suction means are provided with a dedicated suction. This suction can advantageously be controlled individually, or can also be sealed individually. Thus, for example, it is possible to provide in the suction path of each holding location or its suction means a lockable valve, which is connected to a vacuum line or a vacuum pump. By opening the valve, the suction means are activated to fix a mounted solar cell by suction. If the valve is closed, partial pressure can no longer be produced, and partial pressure present in the porous material or in the suction path is re-equalized by a solar cell which is not applied in a fully airtight fashion by virtue of the fact that the partial vacuum is, as it were, assimilated to normal pressure, and the force for holding the solar cell is gradually dissipated. For as fast a release of the solar cell as possible, it is possible to provide one vent valve per suction means so that even an individual solar cell can be removed from its holding location. Alternatively, a vent valve can be provided for a number of, or all, the holding locations or the entire carrier in order to release the solar cells quickly.

The carrier can be designed such that it has a carrier plate in which cutouts have been introduced. Functional devices such as the suction means or the like are inserted into these cutouts. Thus, a carrier plate can be produced relatively easily, and various functional devices, possibly differing in size, design and build, can be inserted. A carrier plate can consist of metal, in particular of a metal plate that is solid or in one piece. In order to save weight, it is possible to mill recesses herein in the usual way. However, otherwise the carrier should be as plane and free from distortion as possible so that the solar cells can be applied as effectively as possible to a glass plate when fabricating the module.

The holes or passages named at the beginning for reaching the solar cell even through the carrier can respectively be formed in a so-called perforated member on a side or an edge of a holding location. Such a perforated member can consist of plastic and be approximately rectangular and have the holes, for example two holes. This perforated member can be inserted into a corresponding recess in the carrier, possibly also into the suction means, in a fashion, which is flush and accurately fitting. By exchanging the perforated member, it is possible to vary the size and number of the holes depending on the method of interconnecting the solar cells, and on the type of the respective solar cells themselves.

In a further refinement of the invention, at least one depression can be provided in the surface of the carrier or the abovementioned carrier plate along two parallel outer sides of the region of the carrier at which the holding locations are provided. A transverse contact wire can be laid in this depression, and in this case it lies near the neighbouring holding locations in such a way that the edges of solar cells mounted thereon lie very near the depression. Contact wires projecting from the solar cells can reach the transverse contact wire with a short length and be fastened thereon by soldering. These trans-verse contact wires interconnect a plurality of strings of solar cells to a module by parallel connection. These strings also form the actual electrical connection of the solar cells or of the module to the outside.

The solar cells are advantageously mounted on an inventive carrier in such a way that the solar cells are prefabricated with contact wires, in particular three contact wires, on their front side. These solar cells are then mounted in an accurately fitting fashion on the carrier at one end of a string or a column of holding locations. A second solar cell is then mounted on the first at a very short spacing in such a way that its underside rests on a projecting region of the contact wire of the preceding solar cell. An electrical connection is then performed, advantageously by soldering. During the soldering time, the next prefabricated solar cell can already be brought up and mounted. This procedure continues until all the solar cells of a string or a column have been mounted on holding locations and soldered.

After all the solar cells have been mounted and soldered with one another and also with the above described transverse contact wires, the carrier, which has up until now advantageously been held at one site during the mounting of the solar cells, is transported further. In this case, the vacuum can be maintained at the suction means, for example by entrained vacuum connection, in particular in the manner of a side chain. Thus, the carrier is moved into a further work station in which it is pivoted by 180° in such a way that the front sides of the solar cells point downwards. Thus, the carrier with the solar cells is mounted in an accurately fitting fashion on a previously prepared glass plate in such a way that the solar cells adjoin the glass plate or a film, arranged thereon and provided for producing a laminate composite, and are held immovably by the properties thereof. The suction means can then be deactivated or the solar cells can be released from the carrier, the carrier is removed and it is then possible to perform the further processing as a finished module in a known way.

Apart from proceeding from the claims, these and other features also proceed from the description and the drawings, it being possible for the individual features respectively to be implemented on their own or severally in the form of subcombinations in an embodiment of the invention and in other fields, and to constitute advantageous embodiments capable of protection per se, for which protection is claimed here. The subdivision of the application into individual sections, and the interpolated headings do not restrict the universal validity in the statements made here.

### BRIEF DESCRIPTION OF THE DRAWINGS

An exemplary embodiment of the invention is illustrated diagrammatically in the drawings and explained in more detail below. In the drawings:

FIG. 1 shows an oblique view of an inventive carrier having a multiplicity of holding locations,

FIG. 2 shows a top view of the carrier in accordance with FIG. 1, and

FIG. 3 shows a much enlarged view of a few holding locations in the detail corresponding to FIG. 2.

### DETAILED DESCRIPTION OF THE EXEMPLARY EMBODIMENT

Illustrated in the figures is a plate-shaped carrier 11, which consists substantially of a thick plate 12. Its dimensions can be just 2 m in length and a little less than 1.5 m in width, but of course can also deviate therefrom, as can the ratio of length to width.

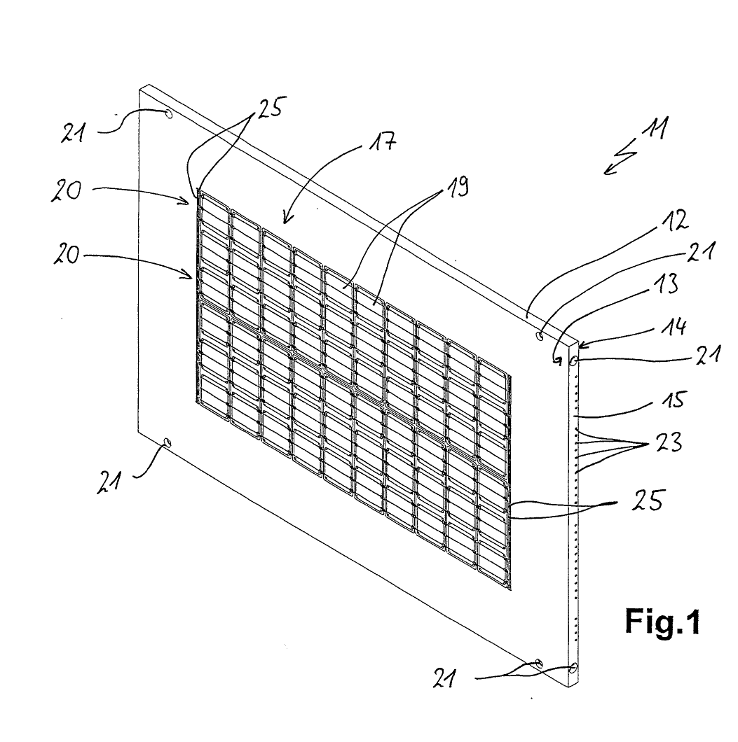

The plate 12 has a substantially even top side 13, and an even underside 14, as well as a right-hand side edge 15, which is to be seen in FIG. 1. The central or middle region of the carrier 11 is formed by a holding location 17 with a multiplicity of inventive holding locations 19. These holding locations 19 are arranged in the manner of columns 20 in the longitudinal direction of the carrier 11, there being, specifically, ten holding locations 19 one after another. Six columns 20 are provided one above another. All the solar cells mounted on these holding locations 19 are then to form a finished module. Of course, the number and/or size can vary. Provided in the corners of the plate 12 of the carrier 11 are grip holes 21 at which the carrier 11, possibly with mounted solar cells, can be handled and moved.

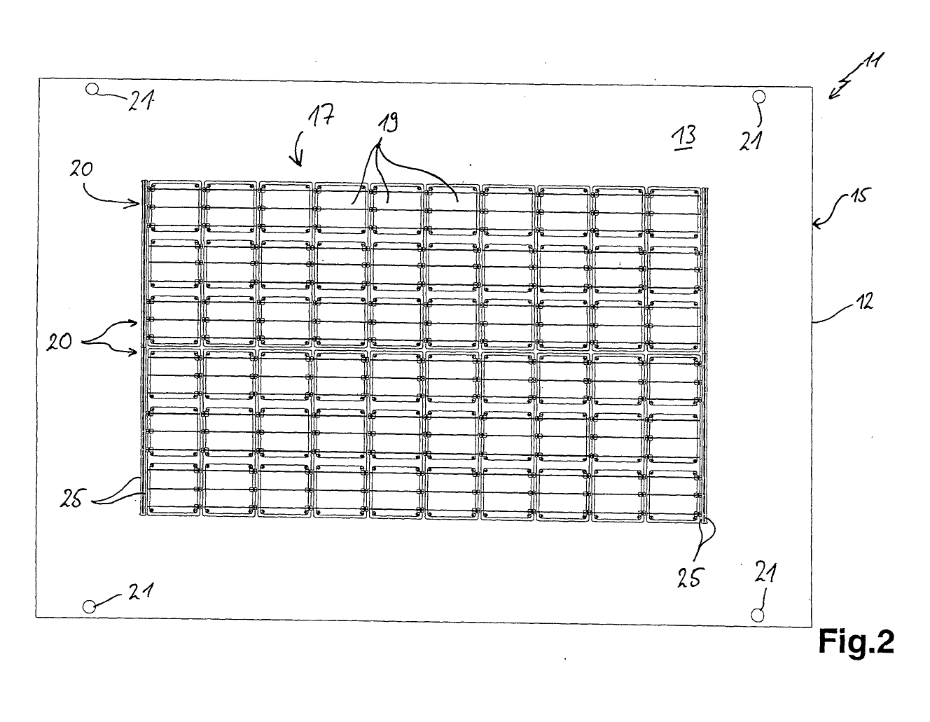

It is chiefly to be seen from FIG. 2 that there are provided close to one another to the left and right of the holding locations 19 two depressions 25, which are a few millimetres deep. As described at the beginning, transverse contact wires are laid in these depressions 25.

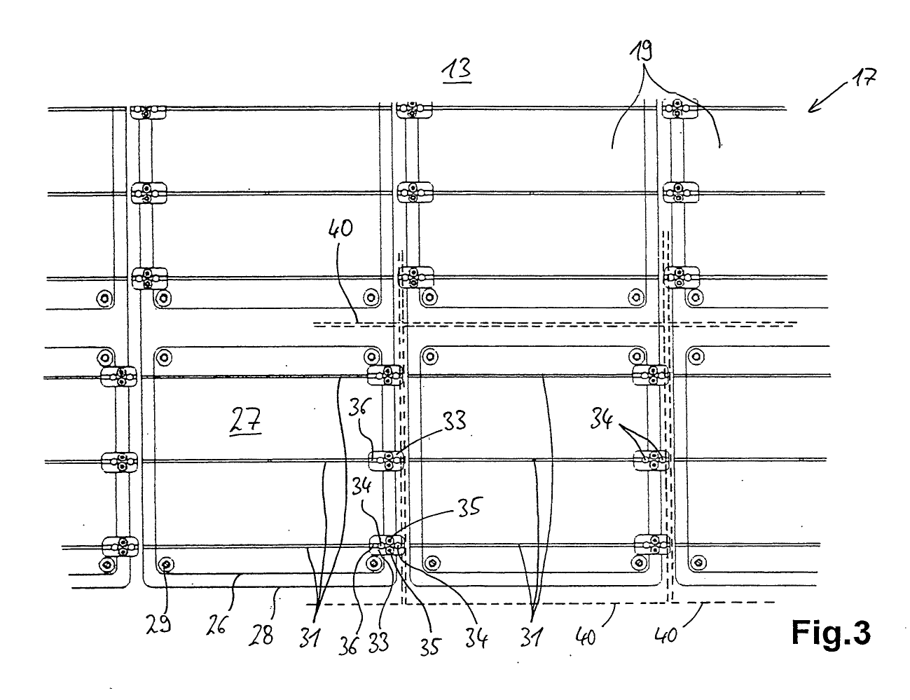

It is to be seen from the enlarged illustration in FIG. 3 that the holding locations 19 have an approximately quadrangular or quadratic suction member 26 with a suction surface 27 as top side. These suction members 26 or the suction surfaces 27 are to lie on the same plane as the surface 13 of the plate 12, or only deviate minimally therefrom, and then rather being somewhat higher. It is, moreover, to be seen that the suction members 26 are not inserted directly into recesses in the plate 12, but rather that the plate 12 has elongated recesses which run from top to bottom and into which elongated plastic frames 28 are inserted. These plastic frames 28 can respectively have three suction members 26. The purpose of the use of these plastic frames 28 resides in the fact that they enable a better fit and tightness towards the side, thereby enabling sealing of the side of the suction member 26, than if the latter were inserted directly into the metal plate 12. The suction member 26, if appropriate together with the plastic frame 28, is screwed down in the plate 12 by means of four fastening screws 29 in the corners.

The suction surface 27 is interrupted by three recesses 31, which run from, left to right in FIG. 3 and are also to be found as a continuation, at least in one region of the plastic frame 28. Contact wires fitted to the underside of a mounted solar cell can lie in these recesses 31 such that the solar cell bears against the suction surface 27 with the largest portion of its surface, and not on the contact wires themselves. This ensures effective support.

Three perforated members 33 are inserted into corresponding cutouts in the suction member 26, plastic frame 28 and plate 12 in extension of the recesses 31, this being done respectively on the right at a suction member 26 and holding location 19. These perforated members 33 advantageously like-wise consist of plastic and have two holes 34 one after another in the longitudinal extent of the recesses 31. Contact wires running in the recesses 31 can be soldered onto a mounted solar cell in the previously described way from below with the aid of a laser beam through these holes 34, which pass through the entire plate 12. A perforated member 33 is fastened by two fastening screws 35. A depression 36 is likewise provided here so that it is possible for the contact wire to run similarly as in the recess 31 in the perforated member 33, as well, which should likewise lie as far as possible with its top side at the level of the suction surface 27.

A few solar cells 40 are further illustrated by dashes. It is to be seen in their case that they are arranged at only a very small spacing, in particular 1 mm to 3 mm, from one another on the holding locations 19 in the holding region 17. It is to be seen, furthermore, that in each case both holes 34 of a perforated member 33 at a holding location 19 are below a solar cell 40, although the outer one is very near the edge. It is provided here that contact wires (not illustrated) of a solar cell 40 lying on the right next to the perforated member 33 are respectively bent from their topside downwards and run in the depression 36 and the recesses 31. A further solar cell 40 is then mounted on the holding location 19 of this perforated member 33 in such a way that its underside comes into contact with the contact wire. Soldering by means of a laser is then undertaken through the holes 34, thus producing a mechanical and, above all, electrical connection between two neighbouring solar cells 40.

The vacuum connections 23 on the right-hand side edge 15 of the carrier 11, of which respectively one leads to a holding location 19, are well in evidence in FIG. 1. The same vacuum connections 23 are provided on the left-hand side edge (not visible) of the carrier 11, for example for the left-hand half of the holding locations 19. Vacuum lines can be connected here, preferably with the valves or shut off means mentioned at the beginning. Such valves or the like can also be fastened directly to the side on the carrier 11 and thus belong to the carrier such that there is a need only for one or two vacuum connections, for example one each per side edge. It is thereby very easy to make a connection with reference to possible vacuum lines.

1. A carrier for a plurality of solar cells intended to be arranged on said carrier, a dedicated holding location being provided for each solar cell on said carrier, wherein said carrier is designed in a plate-like fashion as a substantially closed plate, each said holding location being provided with suction means for a solar cell arranged thereon, wherein said suction means are distributed in two dimensions or extended in two dimensions at said holding location, a plurality of small holes or passages being provided per said holding location in order to get at an underside of said solar cell mounted thereon or to reach an underside of said solar cell mounted thereon also from an underside of said carrier.

2. The carrier according to claim 1, wherein said holding locations are substantially of the same design.

3. The carrier according to claim 1, wherein all said holding locations are equally distributed at an equal spacing from one another.

4. The carrier according to claim 3, wherein all said holding locations are distributed along rows and columns.

5. The carrier according to claim 1, wherein said suction means cover the largest region of said area of said holding location.

6. The carrier according to claim 5, wherein said suction means cover at least 80%.

7. The carrier according to claim 1, wherein said suction means are provided in the central region of said holding location.

8. The carrier according to claim 7, wherein said suction means expose only a narrow edge region of said holding location.

9. The carrier according to claim 1, wherein said suction means have a surface made from an air-pervious or porous material.

10. The carrier according to claim 9, wherein said surface is approximately in a plane with said carrier.

11. The carrier according to claim 9, wherein said air-pervious material is substantially sealed to a side and downwards, and a vacuum connection is connected for the purpose of suction.

12. The carrier according to claim 9, wherein said suction takes place from below.

13. The carrier according to claim 1, wherein each said holding location is provided with its own suction, which can be individually driven and/or closed.

14. The carrier according to claim 1, wherein it has a carrier plate with cutouts, wherein functional devices such as said suction means or the like are inserted into said cutouts.

15. The carrier according to claim 1, wherein said holes or said passages are formed on a side or on an edge of said holding location in a perforated member, it being possible for said perforated member to be inserted into a corresponding recess in said carrier in a fashion which is flush and accurately fitting in order to vary size and/or number of said holes or said passages by replacing said perforated member.

16. The carrier according to claim 1, wherein at least one depression is provided in a surface of said carrier along two parallel outer sides of a region of said carrier with said holding locations, in order to lay transverse contact wires for said electrical interconnection of said solar cells as module.

17. A method for producing an assembly of solar cells by using a carrier according to claim 1, wherein said solar cells are mounted individually in sequence along a column of said holding locations, and each said mounted solar cell starting from a second solar cell is electrically connected to a previously mounted solar cell.

18. The method according to claim 17, wherein said electrical connection by soldering contact wires which have been provided on said previously mounted solar cell.

19. The method according to claim 17, wherein after all said solar cells have been mounted on said carrier, said carrier is moved further from a station used to mount said solar cells up to a station wherein a joining takes place with a glass plate, said suction means continuing to remain activated by application of partial pressure at least during a portion of said transport section.

20. The method according to claim 17, wherein in order to connect said solar cells to a glass plate, said carrier with said solar cells is tilted and/or rotated such that said solar cells point downwards with their previously upwardly pointing front sides, said carrier with said solar cells then being mounted on said glass plate, and subsequently said solar cells being released from said carrier or said holding locations and suction means for the purpose of removing said carrier.
